(19) United States
(12) Patent Application Publication
(10) Pub. No.: US 2001/0050936 A1
(43) Pub. Date: Dec. 13, 2001

(54) Logic determination device for semiconductor integrated device and logic determination method

(76) Inventor: Masaru Sanada, Tokyo (JP)

Correspondence Address: McGuireWoods, 1750 Tysons Boulevard, Suite 1800, Tysons Corner, McLean, VA, 22102-4215, US

(21) Appl. No.: 09/876,051

(22) Filed: Jun. 8, 2001

(30) Foreign Application Priority Data
Jun. 12, 2000 (JP) 175969/2000

(51) Int. Cl. H01S 5/00

(52) U.S. Cl. 372/50

(57) ABSTRACT

By the irradiation of a laser beam in an arbitrary cycle, as well as operating a coefficient obtained by Fourier transform of a power supply current waveform (IDDQ) obtained at the irradiation of no laser and a coefficient obtained by Fourier transform of a waveform (IDDQ+Iph) obtained by superposing a power supply current waveform obtained at the irradiation of laser and photoelectric current waveform Iph to display and compare the coefficients in a graph, existence/nonexistence of Iph can be detected. In addition, simultaneous irradiation of a plurality of positions of PN junctions of an LSI with a laser beam in different cycles enables simultaneous determination of a plurality of positions.

### BACKGROUND OF THE INVENTION

1. Field of the Invention

The present invention relates to a logic determination device for a semiconductor integrated device for use in making determination of internal circuit logic of a CMOSLSI using a laser beam and a logic determination method, and more particularly, to a device and a method suitable for making determination of logic in an LSI having a large amount of through current in a normal state.

2. Description of the Related Art

There have conventionally been two kinds of systems for verifying a logical state inside an LSI using laser.

One is a system of verifying logic by irradiating a drain region of a transistor which forms an output terminal of an arbitrary internal logic circuit with laser. The principle of verification of a logical state of an internal circuit according to this system is introduced in “F. J. Henley: Logic Failure Analysis of CMOS VLSI Using a Laser Probe, IEEE 1984 International Reliability Physics Symposium, pp. 69-75”.

The other is a system of verifying logic by rendering a wiring from an output terminal of an arbitrary internal logic circuit, when the wiring is connected to an input terminal of a subsequent internal logic circuit, conductive with an electrically independent region formed of impurities inverse to those of an LSI substrate and irradiating the region with laser. The principle of the verification of a logical state of an internal circuit is introduced, for example, in Japanese Patent No. 2727799.

Since both of the above-described systems have the same fundamental principles, description as a conventional system will be made of the latter system of verifying a logical state inside an LSI using laser.

FIG. 10 is a diagram for use in explaining this principle, with reference to which description will be made of an inverter circuit formed on a p-type LSI substrate.

FIG. 10 shows an example of a structure in which an inverter circuit 100 and its output wiring 101 are conductive with an N-type impurity region (hereinafter referred to as an N region) provided on a p-type LSI substrate 102. More specifically, the inverter circuit 100 is a circuit having a Pch-MOS transistor 103 and an Nch-MOS transistor 104 connected in series, with a source electrode of the transistor 103 connected to a VDD (highest potential) and a source electrode of the transistor 104 connected to a GND (lowest potential). Gate electrodes of the transistors 103 and 104 are connected to each other to form an input terminal 105 and drain electrodes of the same are connected to each other to form an output terminal 106 whose output wiring 101 is connected to an N region 107 provided on the P-type LSI substrate 102.

FIG. 11 shows an example of operation performed when a high level voltage Hi is applied to the input terminal 105 of the inverter circuit 100.

With a current detector 108 connected in a manner as shown in the figure, when the high level voltage Hi is applied to the input terminal 105, the transistor 103 is turned off and the transistor 104 is turned on, so that a low level potential appears on the output terminal 106. In this state, irradiation of laser onto the N region 107 on the substrate 102 on which the output wiring 101 is provided generates electron-hole pairs in the N region 107, so that electrons flow to the source electrode through a channel region of the transistor 104 being on through the wiring, while holes flow to the GND electrode reversely biasing the P-type LSI substrate 102. Then, at the GND electrode, because of re-coupling between excited electrons and holes, no photoelectric current Iph is detected at the current detector 108.

FIG. 12 shows an example of operation performed when a low level voltage Low is applied to the input terminal 105 of the inverter circuit 100.

When the low level voltage Low is applied to the input terminal 105, the transistor 103 is turned on and the transistor 104 is turned off, so that a high level potential appears on the output terminal 106. In this state, irradiation of laser onto the N region 107 on the substrate 102 on which the output wiring 101 is provided generates electron-hole pairs in the N region 107, so that electrons flow to the source electrode to which VDD is applied through a channel region of the transistor 103 being on through the wiring, while holes flow to the GND electrode reversely biasing the substrate 102. Accordingly, since excited electrons and holes flow to electrodes whose polarities are opposite to each other, respectively, photoelectric current Iph flows and is detected by the current detector 108.

Verification of a logical state inside an LSI using laser according to the above-described respective systems is composed only of the irradiation of each LPP with a laser beam and detection of photoelectric current Iph.

In the following description, the N region 107 for use in verifying logic by the irradiation of laser will be referred to as LPP (Laser Probing Pad).

The above-described conventional methods pose the following problems to an LSI having a power supply current (hereinafter recited as IDDQ) in a static state of logic involving through current in the normal state.

Although photoelectric current Iph generated by the irradiation of a PN junction of an LPP with a laser beam can be increased up to about 10 micro A by shortening a wavelength of a beam of laser to be irradiated or by increasing irradiation power, because an IDDQ value involving a large amount of through current in the normal state ranges from several milli-A to several tens milli-A, a rate of Iph to a power supply current (IDDQ+Iph) will be extremely small, from 1/1000 to less than 1/10,000. It is therefore difficult to discriminate between generation and non-generation of Iph in such an LSI.

Another problem is that logic can not be determined in the plural simultaneously by the irradiation of a plurality of LPPs with laser.

### SUMMARY OF THE INVENTION

An object of the present invention is to provide a logic determination device for a semiconductor integrated device and a logic determination method enabling detection of a small amount of photoelectric current at the determination of the semiconductor integrated device.

According to the first aspect of the invention, a determination device for a semiconductor integrated device comprises

laser irradiation means for irradiating a PN junction of a semiconductor integrated device with a laser beam in an arbitrary cycle, and

detection means for detecting power supply current flowing through the semiconductor integrated device not being irradiated with the laser beam and current obtained by superposing power supply current flowing through the semiconductor integrated device being irradiated with the laser beam and photoelectric current.

In the preferred construction, the determination device for a semiconductor integrated device further comprises operation means for operating a first coefficient obtained by Fourier transform of a waveform of the detected power supply current flowing through the semiconductor integrated device not being irradiated with the laser beam and a second coefficient obtained by Fourier transform of a waveform of the current obtained by superposing the power supply current flowing through the semiconductor integrated device being irradiated with the laser beam and the photoelectric current.

In another preferred construction, the determination device for a semiconductor integrated device further comprises display means for displaying a graph plotting the operated first coefficient and second coefficient.

In another preferred construction, the determination device for a semiconductor integrated device further comprises display means for displaying a difference between the power supply current waveform of the semiconductor integrated device not being irradiated with the laser beam and the current waveform obtained by superposing the power supply current of the semiconductor integrated device being irradiated with the laser beam and the photoelectric current.

In another preferred construction, the determination device for a semiconductor integrated device further comprises operation means for operating a first coefficient obtained by Fourier transform of a waveform of the detected power supply current flowing through the semiconductor integrated device not being irradiated with the laser beam and a second coefficient obtained by Fourier transform of a waveform of the current obtained by superposing the power supply current flowing through the semiconductor integrated device being irradiated with the laser beam and the photoelectric current, first display means for displaying a graph plotting the operated first coefficient and second coefficient, and second display means for displaying a difference between the power supply current waveform of the semiconductor integrated device not being irradiated with the laser beam and the current waveform obtained by superposing the power supply current of the semiconductor integrated device being irradiated with the laser beam and the photoelectric current.

In another preferred construction, the laser beam irradiation means simultaneously irradiates PN junctions at a plurality of positions of the semiconductor integrated device in different cycles and the detection means conducts the detection with respect to each position.

In another preferred construction, the semiconductor integrated device has a large amount of through current flowing in the normal state.

According to the second aspect of the invention, a method of determining a semiconductor integrated device comprising the steps of

a laser irradiation step of irradiating a PN junction of a semiconductor integrated device with a laser beam in an arbitrary cycle, and

a detection step of detecting power supply current flowing through the semiconductor integrated device not being irradiated with the laser beam and current obtained by superposing power supply current flowing through the semiconductor integrated device being irradiated with the laser beam and photoelectric current.

In the preferred construction, the method of determining a semiconductor integrated device further comprises an operation step of operating a first coefficient obtained by Fourier transform of a waveform of the detected power supply current flowing through the semiconductor integrated device not being irradiated with the laser beam and a second coefficient obtained by Fourier transform of a waveform of the current obtained by superposing the power supply current flowing through the semiconductor integrated device being irradiated with the laser beam and the photoelectric current.

In another preferred construction, at the laser beam irradiation step, PN junctions at a plurality of positions of the semiconductor integrated device are simultaneously irradiated in different cycles and at the detection step, the detection is conducted with respect to each position.

According to the third aspect of the invention, a computer readable memory storing a determination program for controlling a computer to make determination of a semiconductor integrated device,

the determination program comprising the functions of

irradiating a PN junction of a semiconductor integrated device with a laser beam in an arbitrary cycle, and

detecting power supply current flowing through the semiconductor integrated device not being irradiated with the laser beam and current obtained by superposing power supply current flowing through the semiconductor integrated device being irradiated with the laser beam and photoelectric current.

According to another aspect of the invention, a determination device for a semiconductor integrated device comprises

laser irradiation unit which irradiates a PN junction of a semiconductor integrated device with a laser beam in an arbitrary cycle, and

detection unit which detects power supply current flowing through the semiconductor integrated device not being irradiated with the laser beam and current obtained by superposing power supply current flowing through the semiconductor integrated device being irradiated with the laser beam and photoelectric current.

In the preferred construction, the determination device for a semiconductor integrated device further comprises operation unit which operates a first coefficient obtained by Fourier transform of a waveform of the detected power supply current flowing through the semiconductor integrated device not being irradiated with the laser beam and a second coefficient obtained by Fourier transform of a waveform of the current obtained by superposing the power supply current flowing through the semiconductor integrated device being irradiated with the laser beam and the photoelectric current.

In another preferred construction, the determination device for a semiconductor integrated device further comprises display unit which displays a graph plotting the operated first coefficient and second coefficient.

In another preferred construction, the determination device for a semiconductor integrated device further comprises display unit which displays a difference between the power supply current waveform of the semiconductor integrated device not being irradiated with the laser beam and the current waveform obtained by superposing the power supply current of the semiconductor integrated device being irradiated with the laser beam and the photoelectric current.

In another preferred construction, the determination device for a semiconductor integrated device further comprises operation unit which operates a first coefficient obtained by Fourier transform of a waveform of the detected power supply current flowing through the semiconductor integrated device not being irradiated with the laser beam and a second coefficient obtained by Fourier transform of a waveform of the current obtained by superposing the power supply current flowing through the semiconductor integrated device being irradiated with the laser beam and the photoelectric current, first display unit which displays a graph plotting the operated first coefficient and second coefficient, and second display unit which displays a difference between the power supply current waveform of the semiconductor integrated device not being irradiated with the laser beam and the current waveform obtained by superposing the power supply current of the semiconductor integrated device being irradiated with the laser beam and the photoelectric current.

In another preferred construction, the laser beam irradiation unit simultaneously irradiates PN junctions at a plurality of positions of the semiconductor integrated device in different cycles and the detection unit conducts the detection with respect to each position.

In another preferred construction, the semiconductor integrated device has a large amount of through current flowing in the normal state.

Other objects, features and advantages of the present invention will become clear from the detailed description given herebelow.

### BRIEF DESCRIPTION OF THE DRAWINGS

The present invention will be understood more fully from the detailed description given herebelow and from the accompanying drawings of the preferred embodiment of the invention, which, however, should not be taken to be limitative to the invention, but are for explanation and understanding only.

In the drawings:

FIG. 1 is a block diagram showing a determination device for a semiconductor integrated device according to an embodiment of the present invention;

FIG. 2 is a graph showing cyclic laser irradiation and a power supply current waveform detected at a power supply terminal of an LSI having a large amount of through current in a normal state;

FIG. 3 is a graph plotting coefficients obtained by Fourier transform of an IDDQ waveform and a waveform obtained by superposing cyclic Iph on the IDDQ waveform;

FIG. 4 is a graph plotting an IDDQ waveform, a power supply current waveform at the time of an analysis and a waveform of Iph detected based on a difference between them;

FIG. 5 is a graph plotting a waveform of Iph detected based on a difference;

FIG. 6 is a structural diagram showing how analyses are made of an LSI surface;

FIG. 7 is a diagram showing a state of the LSI surface;

FIG. 8 is a structural diagram showing how analyses are made of a backside of the LSI;

FIG. 9 is a diagram showing a state of the backside of the LSI;

FIG. 10 is a structural diagram showing a state of a conventional inverter circuit logic analysis using laser;

FIG. 11 is a structural diagram showing a state of generation of photoelectric current Iph when “Hi” is applied to an input of the inverter circuit;

FIG. 12 is a structural diagram showing a state of generation of photoelectric current Iph when “Low” is applied to the input of the inverter circuit.

### DESCRIPTION OF THE PREFERRED EMBODIMENT

The preferred embodiment of the present invention will be discussed hereinafter in detail with reference to the accompanying drawings. In the following description, numerous specific details are set forth in order to provide a thorough understanding of the present invention. It will be obvious, however, to those skilled in the art that the present invention may be practiced without these specific details. In other instance, well-known structures are not shown in detail in order to unnecessary obscure the present invention.

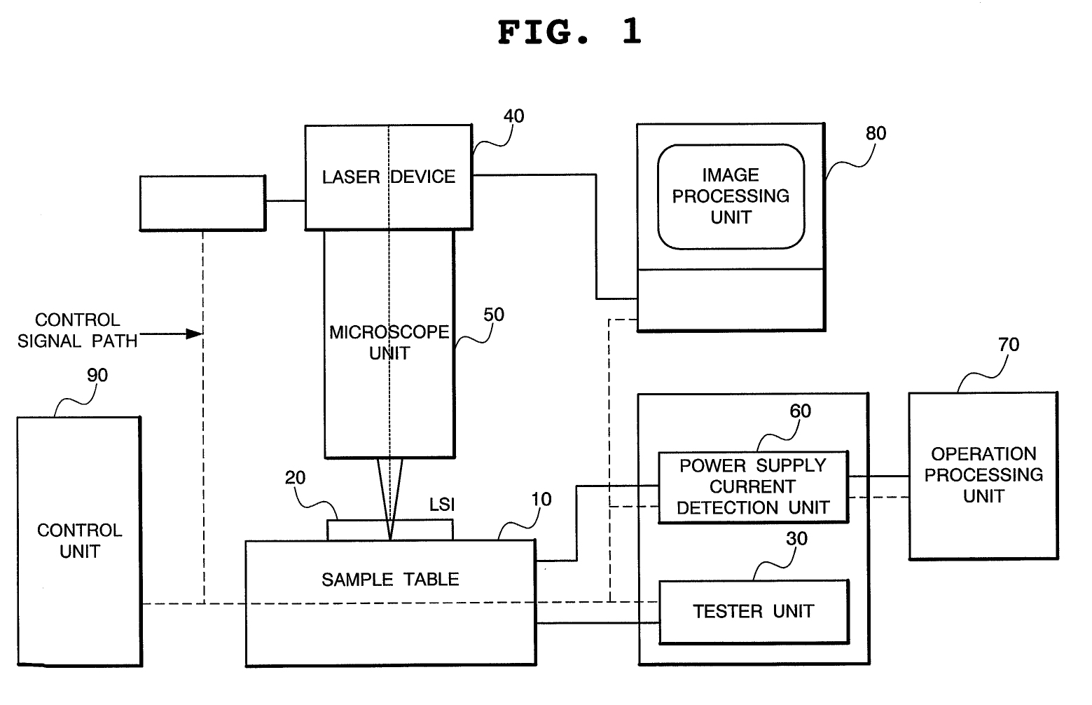

FIG. 1 is a block diagram showing a determination device for a semiconductor integrated device according to an embodiment of the present invention.

In FIG. 1, to an LSI 20 to be analyzed which is placed on a sample table 10 and whose chip surface is exposed, a power supply voltage and an input signal are supplied from a tester unit 30. Provided above the LSI 20 are a laser device 40 and a microscope unit 50 which introduces a beam of laser onto the LSI 20.

A power supply current waveform containing photoelectric current Iph generated by laser irradiation and a value of the same are applied to a power supply current detection unit 60 and based on detected data, determination whether Iph is generated or not is made by an operation processing unit 70. Irradiation state can be visually displayed and monitored by an image processing unit 80. These operations and functions are designed such that a control unit 90 controls timing of laser oscillation, acquisition and operation of power supply current, and image output of an irradiation state.

Next, description will be made of operation of determining internal logic of the LSI 20 having a large amount of through current in the normal state which is conducted by thus structured determination device for a semiconductor integrated device.

In the present embodiment, laser irradiation of a PN junction of an LPP which is conductive with an output wiring of a circuit to be searched is conducted at an arbitrary cycle timing.

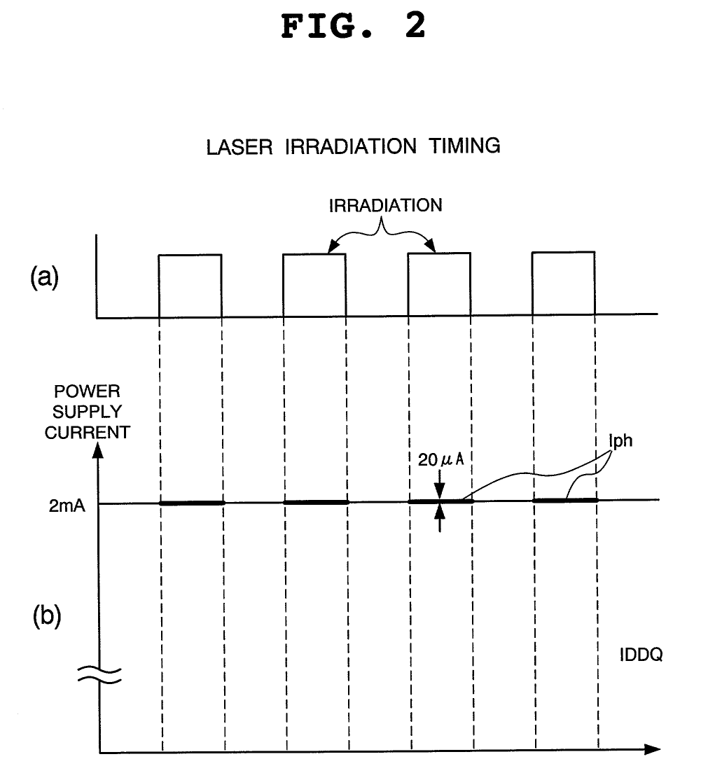

FIG. 2 shows the cyclic laser irradiation and a power supply current waveform detected at a power supply terminal of the LSI 20 having a large amount of through current in the normal state. FIG. 2(a) shows how a beam of laser is cyclically irradiated, with a strength of the laser beam on the ordinate and a cycle of the same on the abscissa. FIG. 2(b) shows a power supply current waveform detected by laser irradiation, with a power supply current value on the ordinate and time on the abscissa.

The power supply current has an IDDQ of about 2 mA. Assume that when an LPP which is rendered conductive with an output wiring clamped to “Hi” is irradiated with laser, Iph of about 20 micro-A is generated. A power supply current waveform detected by laser irradiation will be a waveform totaling the IDDQ of 2 mA and cyclically flowing Iph of 20 micro-A. Since a current detector digital meter observes current in the range of mA, it is difficult to observe about one-hundredth the precision because of an error of its measuring precision.

However, by observing a waveform, it is possible to make its error noticeable. There are two manners for making an error more noticeable.

First manner is Fourier-transforming a waveform to search the same cycle as that of an incident light.

Waveform can be in general displayed as an addition of coefficients of a fundamental wave and its harmonics. A power supply current waveform in which IDDQ is seen before irradiation and a waveform having a cycle of Iph because of cyclic laser irradiation can be detected as a conspicuous difference as a result of the above-described Fourier transform.

The above-described detection is executed by the processing of the power supply current detection unit 60 and the operation processing unit 70 under the control of the control unit 90.

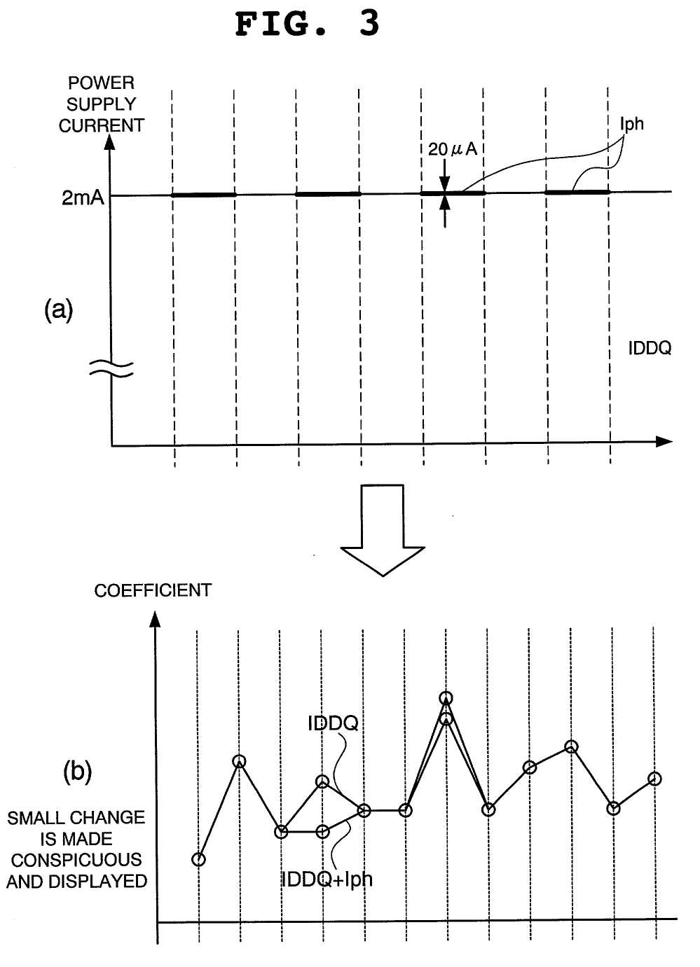

FIG. 3 is a graph plotting coefficients obtained by Fourier transform of an IDDQ waveform and a waveform obtained by superposing cyclic Iph on the IDDQ waveform. FIG. 3(a) is a power supply current waveform shown in FIG. 2(a), while FIG. 3(b) is a graph plotting a coefficient obtained by Fourier transform of the waveform, with a coefficient on the ordinate and a frequency on the abscissa. FIG. 3(b) shows detection of the existence of Iph having only about one-hundredth signal.

Second manner is detecting existence/nonexistence of Iph directly from a waveform. More specifically, by extracting, from a detected power supply current waveform, an IDDQ component which occupies 99% of the waveform, search for existence/nonexistence of Iph based on verification of the remaining 1% of the waveform.

Extract an IDDQ waveform in advance and cyclically irradiate a PN junction of an LPP with laser to obtain a difference between a detected power supply current waveform and the IDDQ waveform. Then, if cyclic Iph is detected together with a little noise, logic at an irradiation point can be specified as “Hi”.

The above-described detection is executed by the processing of the power supply current detection unit 60 and the operation processing unit 70 under the control of the control unit 90.

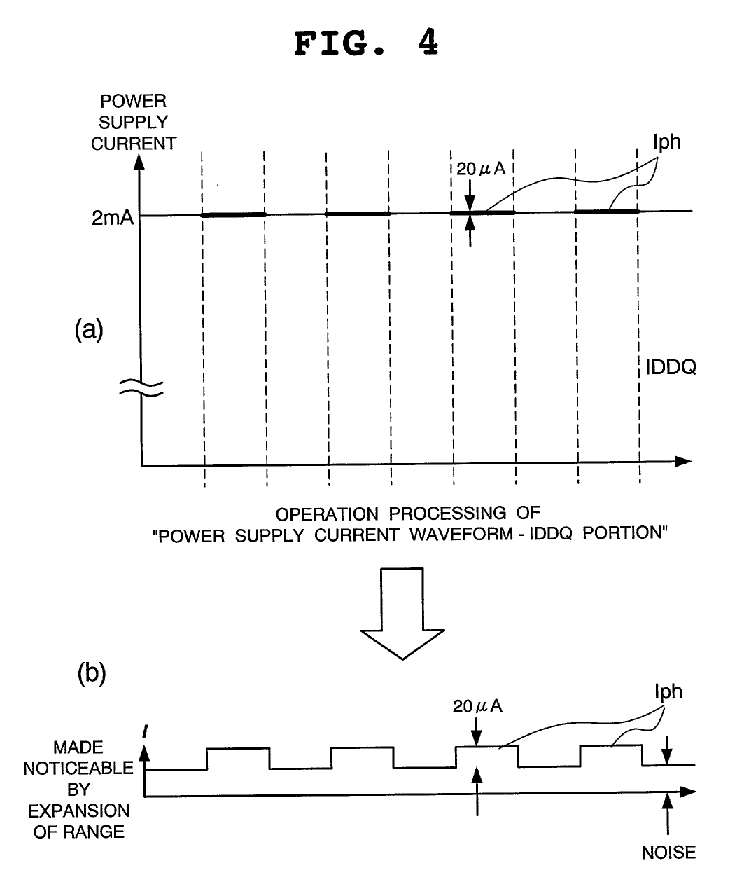

FIG. 4 is an explanatory diagram showing the above-described second method, in which FIG. 4(a) illustrates the power supply current waveform of FIG. 2(a) and FIG. 4(b) is a graph plotting an expanded range of a waveform of Iph made noticeable when a difference of power supply current waveform (IDDQ) before irradiation is calculated from a power supply current waveform (IDDQ+Iph) at an analysis, which shows detection of a cyclic waveform.

Moreover, when determination is difficult, existence/non-existence of Iph can be determined with ease based on a comparison with a coefficient obtained by Fourier transform in the same manner as described above.

Next, description will be made of a method of simultaneously searching logic at a plurality of positions of the LSI 20.

In the present embodiment, logic at a plurality of positions are simultaneously determined, with a plurality of different cycles prepared as many as the number of the measuring points as laser irradiation cycles.

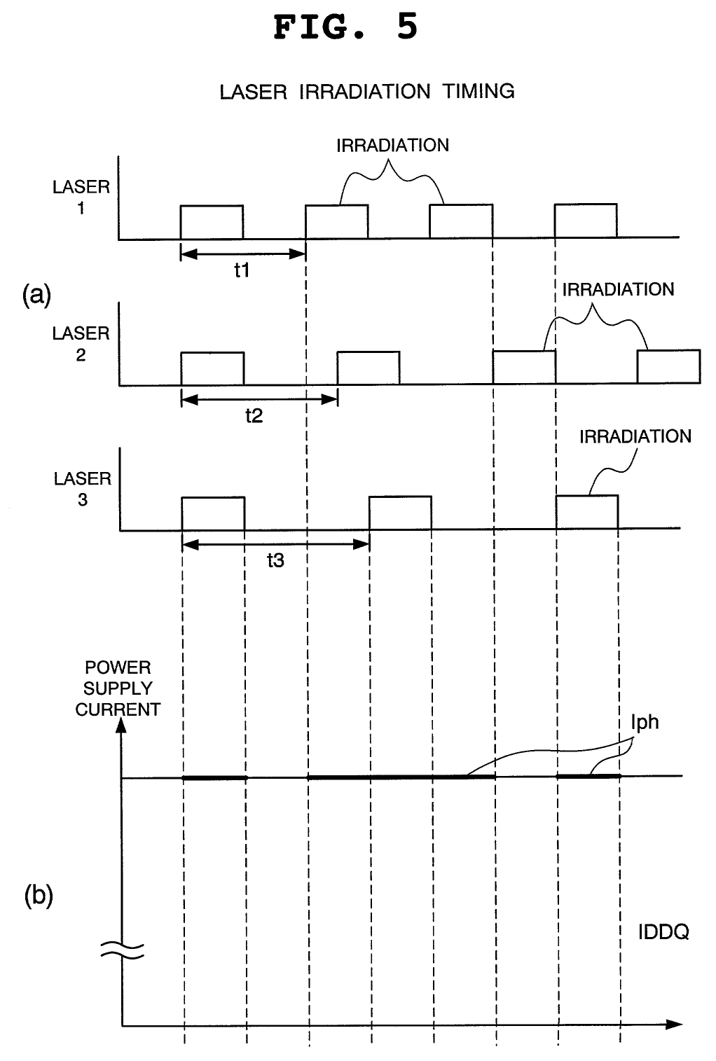

FIG. 5 is a graph showing a relationship between laser irradiation and a power supply current waveform, which example shows how PN junctions at three positions of an LPP are simultaneously measured. FIG. 5(a) shows irradiation states of three laser beams 1, 2 and 3 having three different oscillation cycles t1, t2 and t3. FIG. 5(b) shows a power supply current waveform detected in these states. In FIG. 5(b), Iph is observed in the oscillation cycles t1 and t3, while no Iph is generated in the oscillation cycle t2 and in this case, logic at the LPP positions irradiated by the lasers 1 and 3 can be detected being “Hi” and logic at the LPP position irradiated by the laser 2 can be detected being “Low”. In addition, detecting a unique coefficient corresponding to each cycle of the power supply current waveform detected by the present method by Fourier transform enables more precise determination of logic at each LPP PN junction.

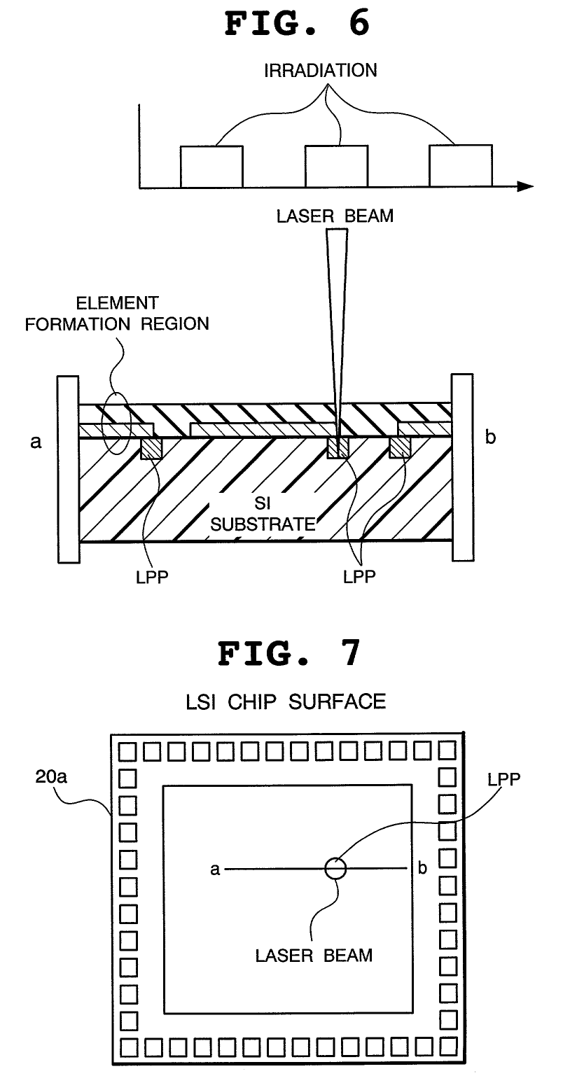

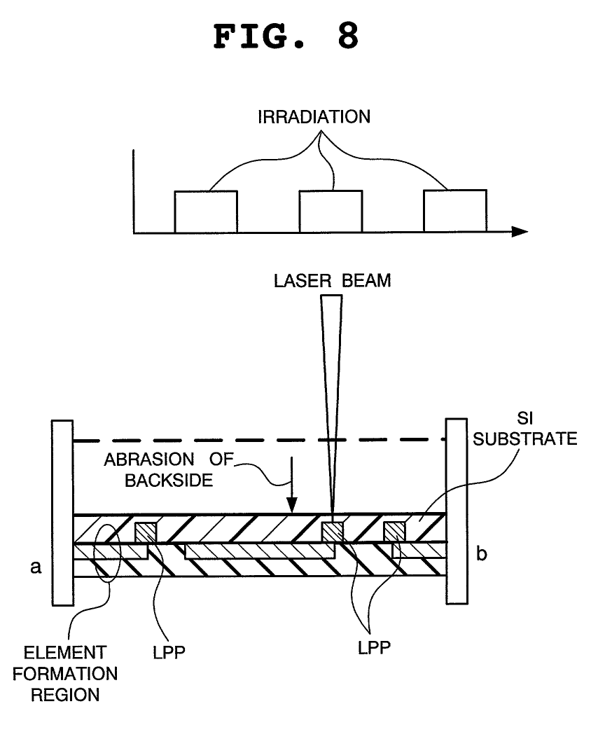

The above-described description is applicable to analyses of both a surface and a backside of an LSI. FIGS. 6 and 7 show how an analysis is made of a surface 20a of the LSI 20. Irradiation of three LPP positions observed from the surface 20a through an insulation film with laser enables analyses of logic. Laser irradiation by means of the laser device 40 is executed under the control of the control unit 90.

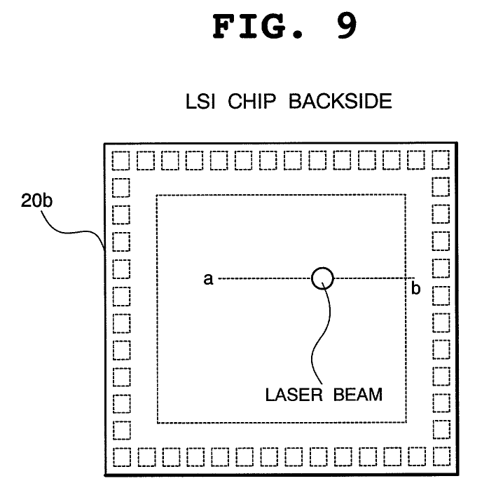

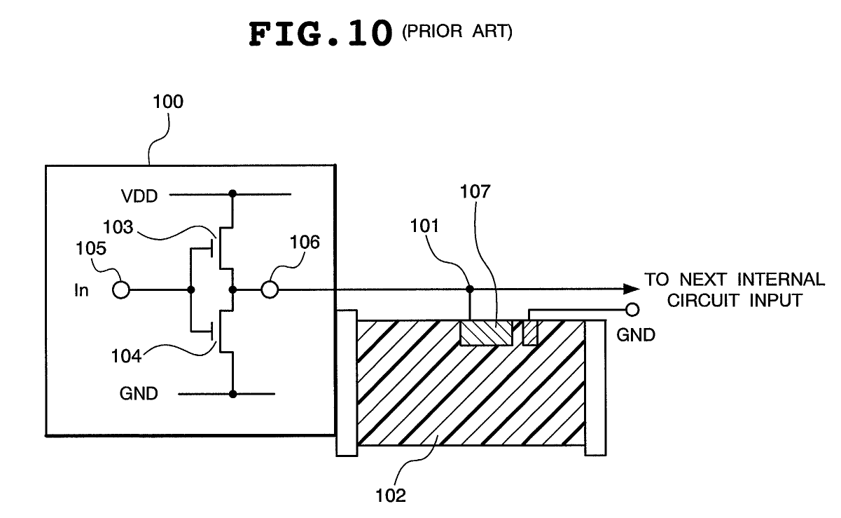

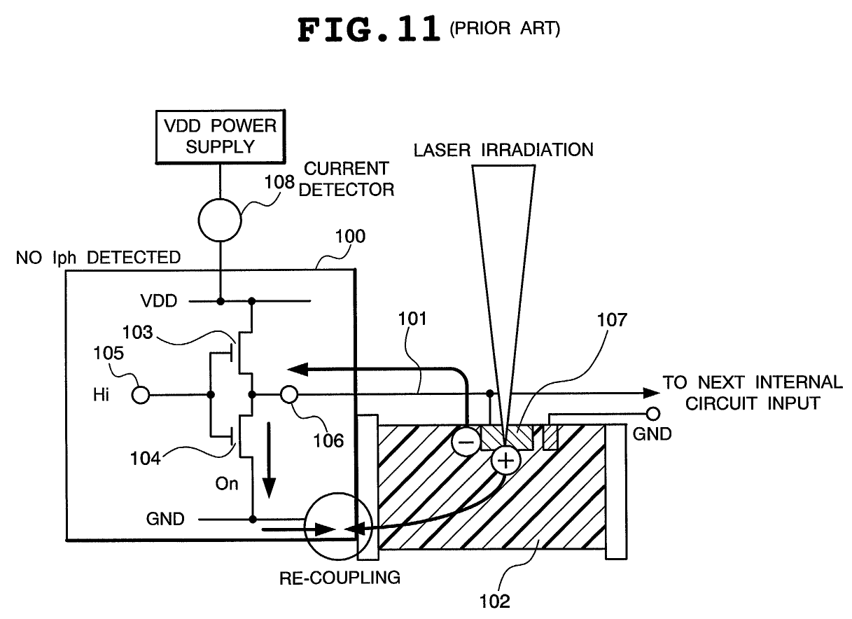

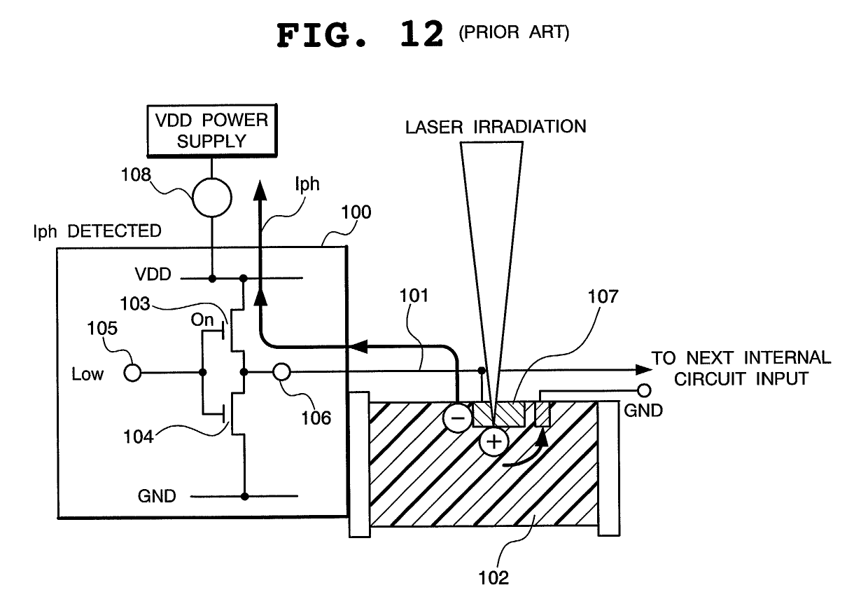

FIGS. 8 and 9 show how an analysis is made of a backside 20b of the LSI 20. In a case of a backside analysis, since irradiated laser beam should reach a PN junction of an LPP, abrasion of an Si substrate surface is required. In recent LSI packaging modes whose representative is a flip-chip package, in particular, an LSI surface and a package mounting surface are packaged facing to each other by a pad portion called bump and accordingly, an LSI seen from the package has its backside facing upward. For analyzing the LSI, therefore, it is necessary to expose an Si surface such that a beam of laser reaches a PN junction and to abrade the Si surface to have a thickness not more than about 200 microns.

Next, description will be made of a computer-readable storage medium according to the present invention.

A storage medium storing a program for a computer having the control unit 90, the operation processing unit 70 and the like to execute a processing procedure based on the above-described operation in the system of FIG. 1 is a computer-readable storage medium according to the present invention.

Used as this storage medium are a semiconductor memory, a magnetic storage medium, a magneto-optical disc, an optical disc and the like which can be formed as a ROM, a RAM, a CD-ROM, a floppy disc, a memory card and the like.

This storage medium includes such a medium holding a program for a fixed time period as a volatile memory such as an RAM in a computer system serving as a server or a client when the program is transmitted through a network such as Internet or a communication line such as a telephone line.

The above-described program may be transmitted from a computer system storing the program in its storage device or the like to other computer system through a transmission medium or a transmission wave in a transmission medium. The transmission medium is assumed to be such a medium having a function of transmitting information as a network (communication network) such as Internet or a communication line (communication wire) such as a telephone line.

In addition, the above-described program may serve to realize a part of the above-described function. Moreover, it may be one that realizes the above-described function in combination with a program already recorded in the computer system, that is, a so-called differential file (differential program).

As described in the foregoing, according to this embodiment, since laser can be handled in the air, analyses of a logical state inside an LSI using laser is enabled with a simple device.

Logic analysis of an LSI having a large amount of through current in the normal state is also enabled.

Furthermore, analyses using simultaneous irradiation with a plurality of lasers enable logic at each irradiated position to be discriminated to high precision and with ease. As a result, internal logic of a large-scale LSI can be specified in a short time period.

Although the invention has been illustrated and described with respect to exemplary embodiment thereof, it should be understood by those skilled in the art that the foregoing and various other changes, omissions and additions may be made therein and thereto, without departing from the spirit and scope of the present invention. Therefore, the present invention should not be understood as limited to the specific embodiment set out above but to include all possible embodiments which can be embodies within a scope encompassed and equivalents thereof with respect to the feature set out in the appended claims.

What is claimed is:

1. A determination device for a semiconductor integrated device comprising:
laser irradiation means for irradiating a PN junction of a semiconductor integrated device with a laser beam in an arbitrary cycle, and
detection means for detecting power supply current flowing through said semiconductor integrated device not being irradiated with said laser beam and current obtained by superposing power supply current flowing through said semiconductor integrated device being irradiated with said laser beam and photoelectric current.

2. The determination device for a semiconductor integrated device as set forth in claim 1, further comprising
operation means for operating a first coefficient obtained by Fourier transform of a waveform of said detected power supply current flowing through said semiconductor integrated device not being irradiated with the laser beam and a second coefficient obtained by Fourier transform of a waveform of the current obtained by superposing the power supply current flowing through said semiconductor integrated device being irradiated with said laser beam and the photoelectric current.

3. The determination device for a semiconductor integrated device as set forth in claim 2, further comprising
display means for displaying a graph plotting said operated first coefficient and second coefficient.

4. The determination device for a semiconductor integrated device as set forth in claim 1, further comprising
display means for displaying a difference between the power supply current waveform of said semiconductor integrated device not being irradiated with said laser beam and the current waveform obtained by superposing the power supply current of said semiconductor integrated device being irradiated with said laser beam and the photoelectric current.

5. The determination device for a semiconductor integrated device as set forth in claim 1, further comprising:
operation means for operating a first coefficient obtained by Fourier transform of a waveform of said detected power supply current flowing through said semiconductor integrated device not being irradiated with the laser beam and a second coefficient obtained by Fourier transform of a waveform of the current obtained by superposing the power supply current flowing through said semiconductor integrated device being irradiated with the laser beam and the photoelectric current,
display means for displaying a graph plotting said operated first coefficient and second coefficient, and
display means for displaying a difference between the power supply current waveform of said semiconductor integrated device not being irradiated with said laser beam and the current waveform obtained by superposing the power supply current of said semiconductor integrated device being irradiated with said laser beam and the photoelectric current.

6. The determination device for a semiconductor integrated device as set forth in claim 1, wherein
said laser beam irradiation means simultaneously irradiates PN junctions at a plurality of positions of said semiconductor integrated device in different cycles and said detection means conducts said detection with respect to each position.

7. The determination device for a semiconductor integrated device as set forth in claim 1, wherein
said semiconductor integrated device has a large amount of through current flowing in the normal state.

8. A method of determining a semiconductor integrated device comprising the steps of:
a laser irradiation step of irradiating a PN junction of a semiconductor integrated device with a laser beam in an arbitrary cycle, and
a detection step of detecting power supply current flowing through said semiconductor integrated device not being irradiated with said laser beam and current obtained by superposing power supply current flowing through said semiconductor integrated device being irradiated with said laser beam and photoelectric current.

9. The method of determining a semiconductor integrated device as set forth in claim 8, further comprising
an operation step of operating a first coefficient obtained by Fourier transform of a waveform of said detected power supply current flowing through said semiconductor integrated device not being irradiated with the laser beam and a second coefficient obtained by Fourier transform of a waveform of the current obtained by superposing the power supply current flowing through said semiconductor integrated device being irradiated with said laser beam and the photoelectric current.

10. The method of determining a semiconductor integrated device as set forth in claim 8, wherein
at said laser beam irradiation step, PN junctions at a plurality of positions of said semiconductor integrated device are simultaneously irradiated in different cycles and at said detection step, said detection is conducted with respect to each position.

11. A computer readable memory storing a determination program for controlling a computer to make determination of a semiconductor integrated device,
said determination program comprising the functions of:
irradiating a PN junction of a semiconductor integrated device with a laser beam in an arbitrary cycle, and
detecting power supply current flowing through said semiconductor integrated device not being irradiated with said laser beam and current obtained by superposing power supply current flowing through said semiconductor integrated device being irradiated with said laser beam and photoelectric current.

12. The computer readable memory storing a determination program for making determination of a semiconductor integrated device as set forth in claim 11,
said determination program further comprising
operating a first coefficient obtained by Fourier transform of a waveform of said detected power supply current flowing through said semiconductor integrated device not being irradiated with the laser beam and a second coefficient obtained by Fourier transform of a waveform of the current obtained by superposing the power supply current flowing through said semiconductor integrated device being irradiated with said laser beam and the photoelectric current.

13. The computer readable memory storing a determination program for making determination of a semiconductor integrated device as set forth in claim 11, wherein
in said determination program,
at said laser beam irradiation function, PN junctions at a plurality of positions of said semiconductor integrated device are simultaneously irradiated in different cycles and at said detection step, said detection is conducted with respect to each position.

14. A determination device for a semiconductor integrated device comprising:
laser irradiation unit which irradiates a PN junction of a semiconductor integrated device with a laser beam in an arbitrary cycle, and
detection unit which detects power supply current flowing through said semiconductor integrated device not being irradiated with said laser beam and current obtained by superposing power supply current flowing through said semiconductor integrated device being irradiated with said laser beam and photoelectric current.

15. The determination device for a semiconductor integrated device as set forth in claim 14, further comprising
operation unit which operates a first coefficient obtained by Fourier transform of a waveform of said detected power supply current flowing through said semiconductor integrated device not being irradiated with the laser beam and a second coefficient obtained by Fourier transform of a waveform of the current obtained by superposing the power supply current flowing through said semiconductor integrated device being irradiated with said laser beam and the photoelectric current.

16. The determination device for a semiconductor integrated device as set forth in claim 15, further comprising
display unit which displays a graph plotting said operated first coefficient and second coefficient.

17. The determination device for a semiconductor integrated device as set forth in claim 14, further comprising
display unit which displays a difference between the power supply current waveform of said semiconductor integrated device not being irradiated with said laser beam and the current waveform obtained by superposing the power supply current of said semiconductor integrated device being irradiated with said laser beam and the photoelectric current.

18. The determination device for a semiconductor integrated device as set forth in claim 14, further comprising:
operation unit which operates a first coefficient obtained by Fourier transform of a waveform of said detected power supply current flowing through said semiconductor integrated device not being irradiated with the laser beam and a second coefficient obtained by Fourier transform of a waveform of the current obtained by superposing the power supply current flowing through said semiconductor integrated device being irradiated with the laser beam and the photoelectric current,
display unit which displays a graph plotting said operated first coefficient and second coefficient, and
display unit which displays a difference between the power supply current waveform of said semiconductor integrated device not being irradiated with said laser beam and the current waveform obtained by superposing the power supply current of said semiconductor integrated device being irradiated with said laser beam and the photoelectric current.

19. The determination device for a semiconductor integrated device as set forth in claim 14, wherein
said laser beam irradiation unit simultaneously irradiates PN junctions at a plurality of positions of said semiconductor integrated device in different cycles and said detection unit conducts said detection with respect to each position.

20. The determination device for a semiconductor integrated device as set forth in claim 14, wherein
said semiconductor integrated device has a large amount of through current flowing in the normal state.
